(19) United States
(12) Patent Application Publication
(10) Pub. No.: US 2012/0239324 A1
(43) Pub. Date: Sep. 20, 2012

(54) BUILDING FACILITY OPERATING STATUS EVALUATING METHOD AND DEVICE

(75) Inventors: Haruka Ueda, Tokyo (JP); Mayumi Miura, Tokyo (JP)

(73) Assignee: YAMATAKE CORPORATION, Tokyo (JP)

(21) Appl. No.: 13/422,199

(22) Filed: Mar. 16, 2012

(30) Foreign Application Priority Data
Mar. 17, 2011 (JP) 2011-059009

(51) Int. Cl. G06F 15/00; G01R 21/00

(52) U.S. Cl. 702/62; 702/182

(57) ABSTRACT

Reported information is classified as to if it is transient reported information due to a transient factor. Time bands within an evaluating interval that are other than time bands wherein air conditioning control has occurred in response to a transient report are defined as evaluation-applicable time bands, and the average energy consumption in the evaluation-applicable time bands is calculated as an energy consumption that serves as a basis value. Moreover, an average of the historical values of energy consumption in the transient report response-controlled air-conditioning time bands is calculated as an energy consumption to serve as a comparison value, and the difference between this energy consumption that is the comparison value and the energy consumption Wbase that is the basis value is calculated as a possible energy savings, and used as un evaluation index indicating the operating status of an air-conditioning device in terms of energy savings.

### CROSS REFERENCE TO RELATED APPLICATIONS

The present application claims priority under 35 U.S.C. §119 to Japanese Patent Application No. 2011-059009, filed Mar. 17, 2011, which is incorporated herein by reference.

### FIELD OF TECHNOLOGY

The present invention relates to a building facility operating status evaluating method and device for obtaining reported information from a user of a building, classifying whether or not the report information that has been obtained is a transient factor, and using the classification results for the reported information to deprive and evaluation index for evaluating the operating status of a facility in the building.

### BACKGROUND

Conventionally, technologies such as those noted below, for example, have been disclosed for producing detailed environments for high comfort in a form wherein information, desires, and the like, of individuals that experience the environment within the area are taken into account:

In order to produce a temperature environment that is pleasing to an individual, a key of a telephone, or the like, that is located in the temperature environment area is used as a temperature perception reported value inputting terminal, where reported values for pleasing perceived temperatures are received through this terminal, where the reported value data and sensor information are subjected to a fuzzy conversion using a membership function, to control air conditioning equipment through performing fuzzy logic based on fuzzy rules (See, for example, Japanese Unexamined Patent Application Publication H5-149601),

Information reported by individuals that indicates the preferences of the individuals regarding the environment and that indicate information regarding the physical facts thereof, and also behavioral information, which comprises the details of requests for changes to the state of environment, which signify the behavior of the occupants within the temperature environment area, and the like, are used to tabulate desires for changes on behalf of the occupants of the temperature environment area, to calculate reporting rates relative to the individual change requests, so that when the reporting rate is greater than a specific reporting rate, then the control b 085815-0215 plan currently in effect for the air-conditioning equipment is changed (See, for example, Japanese Unexamined Patent Application Publication

b 2010-25547). These technologies make it possible to secure comfort that is satisfactory to the occupants by obtaining information regarding the environment reported by the occupants and then modifying the operation of the air-conditioning equipment (by, for example, changing the air-conditioning control setting values). In the living space, there is a trade-off relationship between energy savings and comfort, and, in consideration of global environmental issues, it is desirable to conserve energy as far as is possible (hereinafter termed “energy savings”). In this case, one must consider sacrificing some degree of comfort; however, if not managed properly the result will be unnecessary sacrifice of comfort. Consequently, when correcting air-conditioning parameters to improve operations, when renovating air-conditioning equipment, and the like, it is necessary to evaluate appropriately not only the energy savings but comfort as well, to evaluate the need for corrections to the air-conditioning parameters and renovations to the air-conditioning equipment, and the scope of renovations, and the like.

In buildings, often the building owners are unable to evaluate easily comfort and energy savings, so evaluations are performed by the professionals who perform the renovations. Additionally, the renovations themselves require substantial time and expense. Consequently, in order to obtain an agreement between the building owners and the professional contractors regarding the performance of renovations it is desirable to have an objective index for evaluating the energy savings and comfort.

However, in a system that modifies the operation of the air-conditioning equipment using information reported by the occupants that indicates their desires, such as dissatisfaction regarding the indoor environment, deriving an evaluation index based simply on such results could not take into account a correct evaluation of energy savings and comfort.

For example, let us assume that there are two buildings, building A and building B, wherein the air-conditioning control of the temperature and the humidity have been exactly identical for both. If, at this time, in building A there are reports of transient dissatisfaction by visitors to a business who walk in from off the street and then leave again, and, in building B there are reports of dissatisfaction from occupants who remain resident within the room for an extended period of time to perform routine work, the effective value for the energy savings and comfort will be totally different in building A from that of building B, even if there are the same number of dissatisfaction reports.

In terms of energy savings, if for example, the number of times that the air-conditioning controlling setting values are changed is equal to the number of times that there have been reports of dissatisfaction, then, to that extent, there will be excessive consumption of energy. In this case, even though there would be the same amount of increased consumption of energy in building A and in building B, in building A it would be a transient increase in temperature, where, in building B, this might not be the case, if one were to derive an evaluation index based on this identically increased energy, the evaluation would be incorrect. The same can be said regarding comfort.

The present invention was created in order to solve this type of problem, and the object thereof is to provide a building facility operating status evaluating method and device able to increase the validity of an evaluation index, to enable a more correct evaluation of the operating status of a facility in a building.

### SUMMARY

In order to achieve such an object, the building facility operating status evaluating method according to an example of the present invention is a building facility operating status evaluating method for a facility that is operated using reported information from a user of a building, including a reported information acquiring step for acquiring reported information from the user; a reported information classifying step for classifying whether or not the acquired reported information is transient reported information due to a transient factor; and an evaluation index calculating step for calculating an evaluation index for evaluating an operating status of a facility in the building based on a classification result of reported information and on the control information regarding the operation of the facility in the building.

For example, when reported information from users indicates dissatisfaction with the environment, this dissatisfaction is an expression of the most salient “discomforts,” and it can be a mixture of static dissatisfaction (when referring to dissatisfaction with a truly poor environment) and transient dissatisfaction (for example, dissatisfaction with the room environment that occurs immediately after returning from outdoors, or dissatisfaction that is produced in a non-static state). The example of the present invention focuses on the necessity to classify the nature of the reported information (whether or not it is transient) when evaluating the operating status of the facility. Given this, there was the realization that the operating status of the facility can be evaluated more correctly by correcting the evaluation index using the result of classification of the reported information.

In the examples of the present invention, user information (gender, occupation, etc.) and information from the security system, and the like (entry/exit information) can be used in classifying the reported information. For example, reported information that is obtained can be classified as to whether or not it is reported information due to a transient factor (that is, transient reported information) through, for example, the use of room occupancy time information for the user, information reported after a given amount of time has elapsed, information regarding the reason for the report, reporting history, reporting patterns amongst the entire user population, and the like. Moreover, in the present invention, the evaluation index may be an evaluation index indicating the operating status in terms of energy, or an evaluation index indicating the operating status in terms of the environment.

As a first example of a case wherein the evaluation index is an evaluation index that indicates the operating status in terms of energy in the present invention, time bands other than time bands wherein the operation of the facility was performed using reported information that are classified as transient reported information, within a specific evaluating interval, are defined as an evaluation-applicable time bands, where an evaluation index may be derived using the total time of the evaluation-applicable time bands and the actual value for energy consumption in operations of the facility during the evaluation-applicable time bands.

Moreover, as another example of a case wherein the evaluation index is an evaluation index indicating the operating status, evaluation-applicable time bands are defined as a specific evaluating interval, and the evaluation index may be derived from a theoretical value (estimated value) for the energy consumed in the case of the theoretical application of operation of the facility wherein the conditions have been modified to the side of achieving energy savings in a time band wherein the facility is operated using reported information that is classified as being transient reported information, and actual results for energy consumed in operating the facility in time bands other than the time bands wherein the facility is operated using the reported information that is classified as being transient reported information. Note that in this case, the calculation of the theoretical value may be through assuming that the theoretical value is a reduction of a specific percentage of the actual results, may be through a calculation using a calculating formula for energy consumption, derived through common means using multivariate analysis, may retrieve and use energy consumption under similar environmental conditions, using a database of actual results of building operations, or may be calculated through various types of energy calculations based on the features of the building.

As an example of a case wherein the evaluation index in the example of the present invention is an evaluation index indicating the operating status in terms of the environment, time bands, of a specific evaluating interval, wherein the operating capability of the facility has fallen into a deficient state are used as the evaluation-applicable time bands, and an evaluation index is derived using the total time of the evaluation-applicable time bands and using the total time of the time bands wherein the facility was operated using reported information classified as being transient reported information, of those evaluation-applicable time bands.

Moreover, time bands outside of time bands wherein the operation of the facility uses reported information classified as transient information, within the specific evaluating interval, may be defined as the evaluation-applicable time band, and the evaluation index may be derived from the total time of the evaluation-applicable time bands and the total time of the time bands wherein, during the evaluation-applicable time bands, the operating capability of the facility has fallen into an insufficient state.

In the present example, the facility in the building is not limited to air conditioning equipment, but rather may be lighting equipment, or the like. Moreover, in the present examples, described above, wherein the evaluation index was an evaluation index indicating the operating status from the perspective of energy, the information indicating the amount of energy consumed is typical control information regarding the operation of a facility within a building, and in the example, described above, of the evaluation index being an evaluation index indicating the operating status in terms of the environment, information indicating a large deficiency in the operating capability of the facility is typical control information regarding the operation of the facility in a building. Moreover, the present example can also be embodied as a building facility operating status evaluating device that uses the building facility operating status evaluating method set forth above.

In the examples of the present invention, reported information is obtained from users of a building, classification is performed as to whether or not the reported information that has been obtained are transient factors, and an evaluation index is derived for evaluating the operating status of the facility within the building based on the classification results for the reported information and on control information pertaining to the operation of the facility within the building, thus enabling an improvement in the validity of the evaluation index, and enabling a more correct evaluation of the operating status of the facilities in the building.

### BRIEF DESCRIPTION OF THE DRAWINGS

FIG. 1 is a diagram illustrating schematically a system that uses an air-conditioning equipment operating status evaluating device of an equipment facilities operating status evaluating device according to the present example.

FIG. 2 is a diagram illustrating an example of a function block of an air conditioning equipment operating status evaluating device for deriving an evaluation index from the perspective of energy (energy savings) as one example of an air conditioning equipment operating status evaluating device illustrated in FIG. 1.

FIG. 3 is a diagram for explaining a specific example of a procedure for calculating for the amount of energy consumed that serves as a basis value in the air-conditioning equipment operating status evaluating device of the examples.

FIG. 4 is a diagram for explaining a specific example of a procedure for calculating for the amount of energy consumed that serves as a basis value in the air-conditioning equipment operating status evaluating device of the examples.

FIG. 5 is a diagram illustrating another example of a function block of an air conditioning equipment operating status evaluating device for deriving an evaluation index from the perspective of energy (energy savings) as another example of an air conditioning equipment operating status evaluating device illustrated in FIG. 1.

FIG. 6 is a diagram for explaining a specific example of a procedure for calculating the theoretical air-conditioning time bands for performing energy-saving control based on the transient reported information in the air-conditioning equipment operating status evaluating device according to another example, and the procedure for calculating the possible energy savings.

FIG. 7 is a diagram for explaining a specific example of a procedure for calculating the theoretical air-conditioning time bands for performing energy-saving control based on the transient reported information in the air-conditioning equipment operating status evaluating device according to the other example, and the procedure for calculating the possible energy savings.

FIG. 8 is a diagram illustrating a function block of an air conditioning equipment operating status evaluating device for deriving an evaluation index from the perspective of the environment (comfort) a further example of an air conditioning equipment operating status evaluating device illustrated in FIG. 1.

FIG. 9 is a diagram for explaining a specific example of a procedure for calculating an insufficient heating/cooling time, for each type of classification results for the reported information in the air-conditioning equipment operating status evaluating device according to the further example.

FIG. 10 is a diagram for explaining a specific example of a procedure for calculating an insufficient heating/cooling time, for each type of classification results for the reported information in the air-conditioning equipment operating status evaluating device according to the further example.

### DETAILED DESCRIPTION

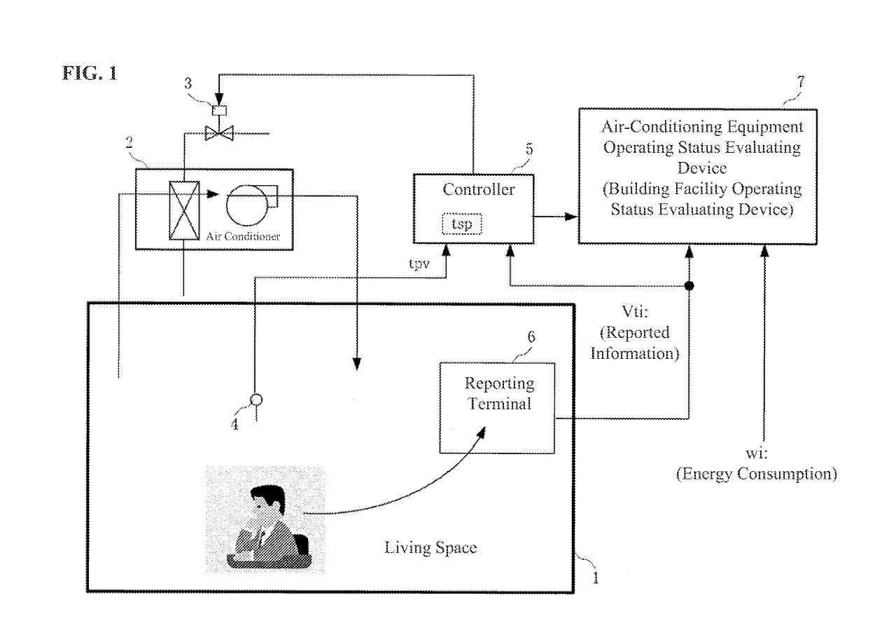

Examples according to the present invention are explained below in detail, based on the drawings. FIG. 1 is a diagram illustrating schematically a system that uses an air-conditioning equipment operating status evaluating device as an examples of an equipment facilities operating status evaluating device according to the present invention.

In this drawing: 1 is a living space; 2 is an air-conditioner for providing conditioned air into the living space 1; 3 is a chilled water valve that is provided in the chilled water supply pipe to the air conditioner 2; 4 is a room temperature sensor for detecting, as the room temperature, the temperature within the living space 1; 5 is a controller for controlling the supply rate of the chilled water to the air conditioner 2; 6 is a reporting terminal that is provided for the living space it; and 7 is an air conditioning equipment operating status evaluating device that is provided, as one example of a building facility operating status evaluating device according to the present invention.

In this air conditioning system, the controller 5 controls the amount of chilled water supplied to the air conditioner 2 through the chilled water valve 3 so that the room temperature tpv within the living space 1, detected by the room temperature sensor 4, matches a setting temperature tsp, to adjust the temperature of the air supplied from the air conditioner 2 to the living space 1.

Moreover, this controller 5 inputs reported information (request reports) Vti from a resident (a user), through a reporting terminal 6, indicating desires, such as dissatisfaction with the room environment, and changes the temperature setting tsp in accordance with the reported information Vti. That is, the reported information Vti is a desire in the direction of being cooler (for example, reducing the temperature) in regards to the perceived temperature of the conditioned environment, where if this temperature setting tsp is a cooling setting value, then the setting value tsp would be changed in the direction of the lower.

Note that in FIG. 1 the reporting terminal 6 may be used by a plurality of people who experience the air-conditioned environment within the living space 1, where one or more reporting terminals 6 is provided within the living space 1.

Additionally, in the examples described below, the temperature setting tsp is resetted to the building-side controlled temperature setting (the building-controlled temperature) tsp_{BIL} at 12:00 midnight, and if reported information Vti is inputted thereafter, then notwithstanding the results for classification of this reported information Vti, the building-controlled temperature tsp_{BIL} is changed in the direction of achieving the reported information Vti. That is, if the reported information Vti is a desire for the temperature to be reduced, the building-controlled temperature tsp_{BIL} is changed in the direction of a 1° C. reduction.

The reported information Vti from the residence, from the reporting terminals 6, is inputted also into the air-conditioning equipment operating status evaluating device 7. Moreover, the energy consumption wi, which changes over time and which is used by the system as a whole, is also inputted into the air-conditioning equipment operating status evaluating device 7. This inputted energy consumption wi corresponds to the typical control information regarding the operation of the facility in the building in the present invention.

The air-conditioning equipment operating status evaluating device 7 is embodied through hardware, including a processor and a memory device, and a program that achieves a variety of functions in cooperation with this hardware, and has, as a function that is unique to the present form of embodiment, an evaluation index calculating function for evaluating the operating status of the air-conditioning equipment.

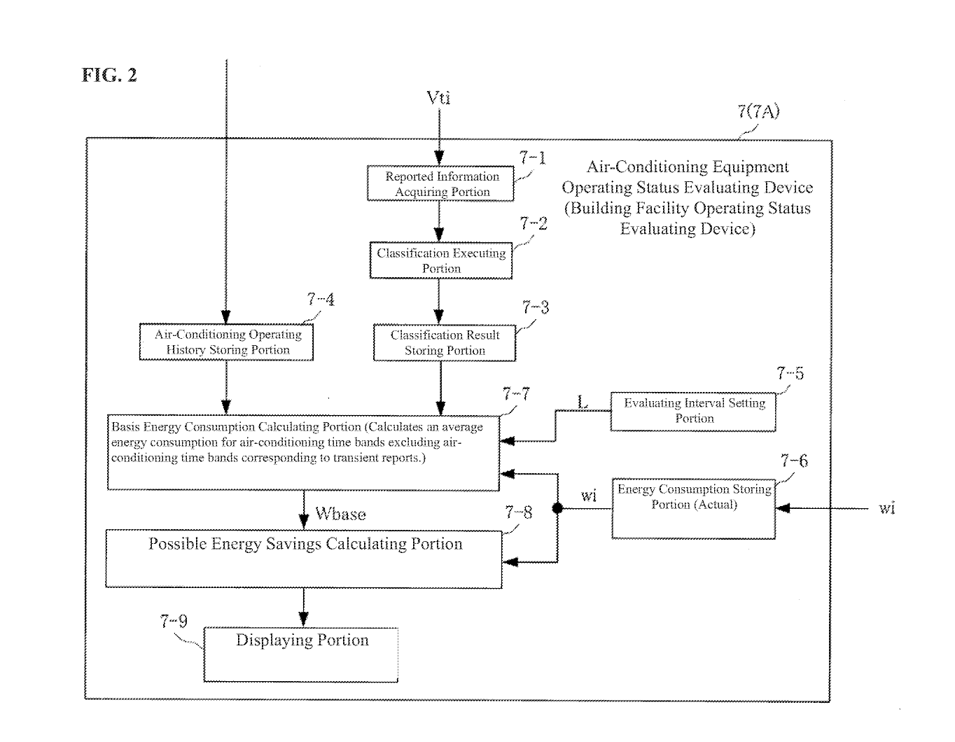

FIG. 2 shows an example of a function block of an air conditioning equipment operating status evaluating device 7 in the case of deriving an evaluation index from the perspective of energy (energy savings) as one example of an air conditioning equipment operating status evaluating device illustrated in FIG. 1.

This air-conditioning equipment operating status evaluating device 7 (7A) is provided with: a reported information acquiring portion 7-1 for acquiring reported information Vti from the reporting terminal 6; a classification executing portion 7-2 for classifying whether or not the reported information Vti, acquired by the reported information acquiring portion 7-1 is transient reported information (hereinafter termed a “transient report”) due to a transient cause; a classification result storing portion 7-3 for storing the classification result for the reported information Vti, classified by the classification executing portion 7-2; and an air conditioning operating history storing portion 7-4 for storing the operating history for air-conditioning control, including the history of changes in the settings for the temperature setting tsp in the controller 5.

The classification executing portion 7-2 classifies whether or not the reported information Vti that has been acquired by the reported information acquiring portion 7-1 is a transient report, where any given algorithm may be used for the classification procedure. For example, it is possible to select a desired classification procedure from Day 5 classification procedures described below, and set it up in the classification executing portion 7-2.

Note that the classification procedure that is used is not limited to these five classification procedures, but rather should be designed as appropriate depending on the characteristics of the building and occupants for which the evaluation procedure is to apply, and on the nature and quantity of information obtained. Moreover, as explained below, the reported information Vti that is not classified by the classification executing portion 7-2 as transient information may be defined as static information (hereinafter termed a “static report”).

### Classifying Procedure 1

A room occupancy time j is calculated from a time t=t1. Additionally, a report Vt1, made at a time t=t1 and a report of entry/exit information S are compared. If the occupancy time j≦k (where k is an arbitrary value), then the classification is that of a transient report (a desire).

### Classifying Procedure 2

A report Vt1 at time t=t1 is compared to the content (or to the existence or nonexistence) of a report Vt2 at a time t=t2 after an arbitrary time u has elapsed, to classify whether or not each report is transient.

### Classifying Procedure 3

Report reason information R is acquired in a report Vt1 at a time t=t1, and if a category that is set as a “transient reason” is selected, the classification is that of being transient.

### Classifying Procedure 4

A report Vt1 at a time t=t1, room environment information Et1 (for example, the room temperature), and a personal report history for the reporting individual are compared, to calculate a matching proportion f thereof, where if the matching proportion f≦k (where k is an arbitrary value), then the classification is that of being transient.

### Classifying Procedure 5

A report Vt1 at a time t=t1, room environment information Et1 (for example, the room temperature), and a reporting pattern (frequency distribution) G of the occupants (in aggregate) of the controlled living space are compared, and if the matching proportion f≦k (where k is an arbitrary value), then the classification is that of being transient.

Note that when using the classification procedures described above, one may consider the use of circadian rhythms (metabolic patterns), past reporting history, resident information (gender, profession, age, etc.), entry/exit information, schedulers (work hours, and the like), external environment information, building/facility information (use application, air-conditioning method, etc.), individual preferences (tendencies to feel hot/cold, etc.), room environment distributions (computational fluid dynamics (CFD), and the like), reporting reasons, and so forth.

Moreover, when calculating the matching proportion f (similarity), one may consider the use of a discriminant function (Mahalanobis's generalized distance: discrimination, double discrimination, and multiple discrimination of whether or not there is membership in a given population), a Euclidean distance, a correlation function, distance between clusters, similarities of histograms (image processing technology), a discrimination method based on a waveform model of time-series data (average behavior calculation: ABC), and the like).

### Function Block for the Evaluation Index Calculation

The air-conditioning equipment operating status evaluating device 7A is further provided with: an evaluating interval setting portion 7-5 for setting an evaluating interval L; an energy consumption storing portion 7-6 for storing an energy consumption wi that is inputted periodically; a basis energy consumption calculating portion 7-7 for calculating, as an energy consumption Wbase that serves as a basis value, an average energy consumption over the air-conditioning time bands that exclude the air-conditioning time bands that correspond to transient reports in the evaluating interval L; a possible energy savings calculating portion 7-8 for calculating a possible energy savings by calculating an energy consumption Wr, to serve as a comparison value, using the energy consumption stored in the energy consumption storing portion 7-6, and comparing this calculated energy consumption Wr with the energy consumption Wbase, which serves as a basis value, calculated by the basis energy consumption calculating portion 7-7; and a displaying portion 7-9 for displaying the possible energy savings calculated by the possible energy savings calculating portion 7-8.

### Calculating the Energy Consumption Rate to Serve as the Basis Value

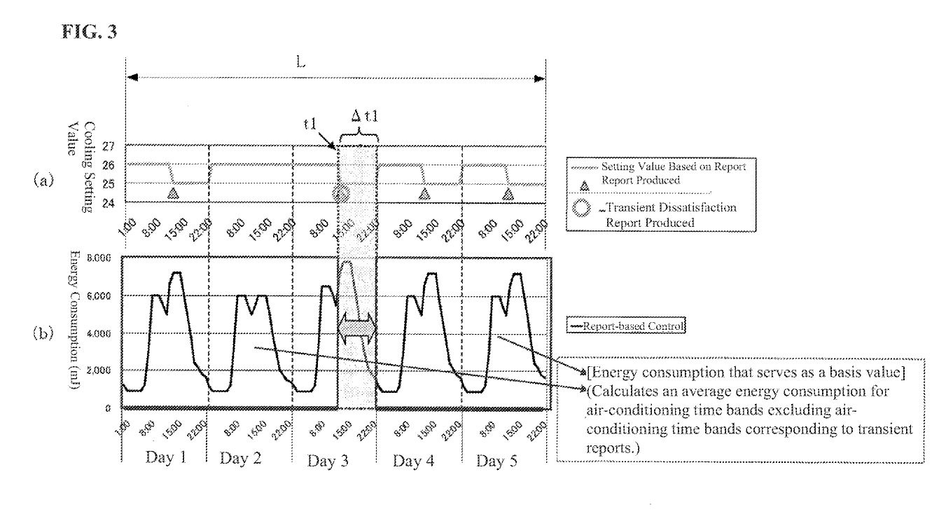

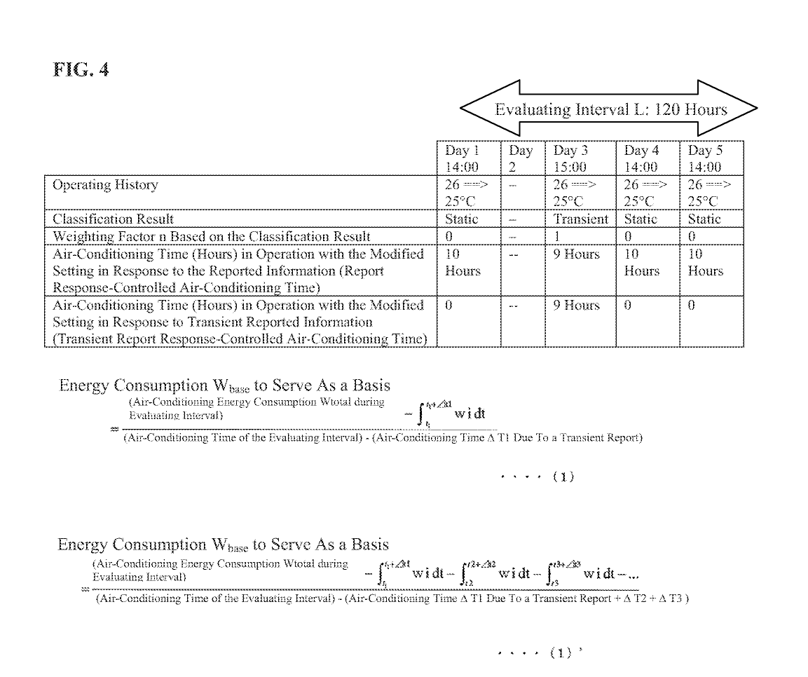

A specific example of the calculation process for the energy consumption Wbase that serves as the basis value in the basis energy consumption calculating portion 7-7 is explained using FIG. 3 and FIG. 4.

Here FIG. 3(a) shows the changes in the cooling setting value tsp during the evaluating interval L, and FIG. 3(b) shows a time series of the actual values wi for the energy consumption during the evaluating interval L. FIG. 4 shows the operating results of the air-conditioning equipment, the classification results for reported information, the weighting factors n that are dependent on the classification results, the air-conditioning time for operation with modified settings in response to reported information (hereinafter termed the report response-controlled air-conditioning time), and the air-conditioning time for operation with modified settings in response to transient reports (hereinafter termed transient report response-controlled air-conditioning time) during the evaluating interval L.

In this example, the evaluating interval L is 120 min. (five hours), where there was a static report at 14:00 on Day 1, a transient report at 15:00 on Day 3, and static reports at 14:00 on Day 4 and 14:00 on Day 5. In order to respond to these, the cooling setting value was changed from 26° C. to 25° C. at 14:00 on Day 1, and returned to 26° C. at “0:00” that night. Moreover, the heating setting value was changed from 26° C. to 25° C. at 15:00 on Day 3, and returned to 26° C. at “0:00” that night. Similarly, the cooling setting value was changed from 26° C. to 25° C. at 14:00 on Day 4 and the heating setting value was changed from 26° C. to 25° C. at 14:00 on Day 5.

In this case, the classification executing portion 7-2 follows the classification procedure that has been set to classify the reports on Day 1, Day 4, and Day 5 as static reports, and classify the report from Day 3 as a transient report, and stores the classification results in the classification result storing portion 7-3. Moreover, the history of the air-conditioning operation during these five days is stored in the air-conditioning operation history storing portion 7-4.

The basis energy consumption calculating portion 7-7 acquires the classification results for the reported information during the evaluating interval L which have been stored in the classification result storing portion 7-3, and defines the weighting factor n as “0” for the case of the classification result being a static report, and defines the weighting factor n as “1” for the case of a transient report. In this case, the weighting factors n are set to “0” for the reports on Day 1, Day 4, and Day 5, because they are static reports, and the weighting factor n is set to “1” for the report on Day 3, because it is a transient report.

Following this, the basis energy consumption calculating portion 7-7 calculates the report response-controlled air-conditioning time based on the history of the air-conditioning operations during the evaluating interval L, which is stored in the air-conditioning operation history storing portion 7-4. In this case, for Day 1 the report response-controlled air-conditioning time was calculated as 10 hours because the cooling setting value was changed from 26° C. to 25° C. at 14:00 and returned to 26° C. at 0:00. Similarly, the report response-controlled air-conditioning time was calculated as nine hours for Day 3, 10 hours for Day 4, and 10 hours for Day 5.

Given this, the basis energy consumption calculating portion 7-7 multiplies the weighting factor n for each of the reports by the report response-controlled air-conditioning times, to calculate the transient report response-controlled air-conditioning time. In this case, for Day 1, Day 4, and Day 5, the weighting factors are “0”, so the transient report response-controlled air-conditioning time is 0 hours. In contrast, for Day 3 the weighting factor n is “1”, and thus the transient report response-controlled air-conditioning time is nine hours.

The basis energy consumption calculating portion 7-7 defines as the evaluation-applicable time band the time bands other than 15:00 through 0:00 on Day 3 (that is, 15:00 on Day 3 through 0:00 on Day 4) that is the time band at which there was air-conditioning control wherein there was operation under a change of settings in response to a transient report, as calculated. (hereinafter termed a transient report response-controlled air-conditioning time band), and calculates, as the energy consumption Wbase that serves as a basis value, the average energy consumption over the evaluation-applicable time band. When, for simplicity in the explanation, the transient report response-controlled air-conditioning time band that occurred on Day 3 is defined as from t1 through t1+Δt1 (where t1 corresponds to the starting time and Δt1 corresponds to the transient report response-controlled air-conditioning time), the energy consumption Wbase that serves as the basis value is calculated using Equation (1), below. Note that while the explanation in the present form of embodiment is for a single transient report response-controlled air-conditioning time band (that is, from t1 through t1+Δt1), if there is a plurality thereof, then Equation (1)′ would apply.

$$\begin{matrix}Equation 1 & \\ Energy Consumption {W}_{base} to Serve As a Basis = \frac{( \begin{matrix}Air \text{-} Conditioning Energy \\ Consumption Wtotal during \\ Evaluating Interval\end{matrix} ) - {\int }_{{t}_{1}}^{{t}_{1} + Δ t 1} wi d t}{( \begin{matrix}Air \text{-} Conditioning Time of \\ the Evaluating Interval\end{matrix} ) - ( \begin{matrix}Air \text{-} Conditioning Time Δ T 1 \\ Due To a Transient Report\end{matrix} )} & ( 1 ) \\ Energy Consumption {W}_{base} to Serve As a Basis = \frac{( \begin{matrix}Air \text{-} Conditioning Energy \\ Consumption Wtotal during \\ Evaluating Interval\end{matrix} ) - {\int }_{{t}_{1}}^{{t}_{1} + Δ t 1} wi d t - {\int }_{{t}_{2}}^{{t}_{2} + Δ t 2} wi d t - {\int }_{{t}_{3}}^{{t}_{3} + Δ t 3} wi d t - …}{( \begin{matrix}Air \text{-} Conditioning Time of \\ the Evaluating Interval\end{matrix} ) - ( \begin{matrix}Air \text{-} Conditioning Time Δ T 1 \\ Due To a Transient Report + \\ Δ T 2 + Δ T 3\end{matrix} )} & ( {1}^{′} )\end{matrix}$$

The possible energy savings calculating portion 7-8 calculates an energy consumption Wr, as a comparison value, using actual values for the energy consumptions stored in the energy consumption storing portion 7-6, and calculates the possible energy savings by comparing this calculated energy consumption Wr with the energy consumption Wbase, which is the basis value, calculated by the basis energy consumption calculating portion 7-7.

For example, the per-unit-time energy consumption from t1 through t1+Δt1, which is a transient report response-controlled air-conditioning time band, is calculated as the energy consumption Wr that serves as the comparison value, and the possible energy savings are calculated by taking the difference between this calculated energy consumption Wr and the energy consumption Wbase that serves as the basis value. These calculated possible energy savings are displayed on the displaying portion 7-9.

Note that while in the present example the energy consumption for the transient report response-controlled air-conditioning time hands were calculated as an energy consumption Wr to serve as a comparison value, and the difference from the energy consumption Wbase, which serves as a basis value, was calculated as the possible energy savings, instead an average value for the historic values of the energy consumptions over the evaluating interval L may be calculated as the energy consumption Wr, and the difference between this calculated energy consumption Wr and the energy consumption Wbase that is the basis value may be calculated as the possible energy savings. When the possible energy savings are displayed to a user, preferably the value that was used for the energy consumption Wr, which is the comparison value, is displayed at the same time.

Moreover, the energy consumption Wbase, which serves as the basis value, and the energy consumption for the transient report response-controlled air-conditioning time band are displayed on the displaying portion 7-9 so as to enable comparisons as an evaluation index, or the energy consumption Wbase that serves as the basis value and the average value for the historic values of the energy consumption over the evaluating interval L may be displayed, so as to enable comparison, on the displaying portion 7-9, as an evaluation index.

The energy consumption Wbase that serves as the basis value, shown in the present example, or an index, such as the possible energy savings, or the like, obtained using the Wbase, corresponds to the evaluation index for the operating status of the facility in the present example. The use of the energy consumption Wbase that serves as the basis value, calculated based on the classification result (i.e., transient vs. static) for the reported information makes it possible to exclude, at the time of the energy evaluation, the effects of reports of transient desires, which cannot be considered to be caused by the performance or operation of the facility, thus enabling a substantial improvement in the validity of the evaluation index, and enabling more correct evaluations of the operating status of the air-conditioning equipment within a building.

Note that while the exclusion, at the time of the energy evaluation, of the effect due to reports of transient desires, which cannot be considered to because by the facility performance or operation, provides an effect of improving the validity of the evaluation, where this evaluation method itself is not limited to a comparison with the Wr shown in the present form of embodiment.

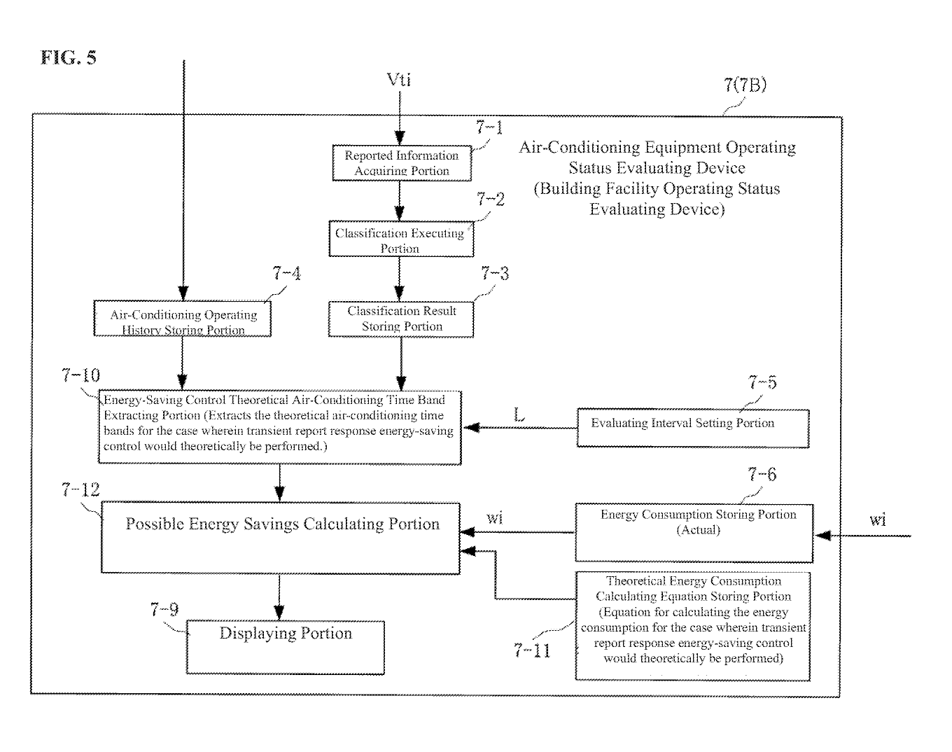

FIG. 5 shows another example of a function block of an air conditioning equipment operating status evaluating device 7 in the case of deriving an evaluation index from the perspective of energy (energy savings) as one example of an air conditioning equipment operating status evaluating device illustrated in FIG. 2.

In this air-conditioning equipment operating status evaluating device 7 (7B), the “function block for reported information classification” is identical to that of the air-conditioning equipment operating status evaluating device 7A in the f above example, so the explanation thereof is omitted.

### Function Block for the Evaluation Index Calculation

This air-conditioning equipment operating status evaluating device 7B is provided with: an evaluating interval setting portion 7-5 for setting an evaluating interval L; an energy consumption storing portion 7-6 for storing energy consumptions wi that are inputted periodically; an energy-saving control theoretical air-conditioning time band extracting portion 7-10 for extracting a theoretical air-conditioning time band if, theoretically, energy-saving control in response to a transient report (hereinafter termed transient report-response energy-saving control) were performed during the evaluating interval L; a theoretical energy consumption calculating equation storing portion 7-11 for recording a calculating equation for the energy consumption in the case of the theoretical execution of transient report-response energy-saving control; a possible energy savings calculating portion 7-12 for calculating, as a possible energy savings, a comparison value (a difference, a ratio, or the like) with an estimated energy consumption, which is an estimated value for the energy consumption in the case of the theoretical execution of transient report-response energy-saving control in response to a transient report during the evaluating interval L, compared to the energy consumption for the actual consumption during the evaluating interval L; and a displaying portion 7-9 for displaying the possible energy savings calculated by the possible energy savings calculating portion 7-12.

Note that in this example, the theoretical energy consumption calculating equation storing portion 7-11 stores a calculating equation, or a calculating method, for calculating an estimated value (theoretical value) for the energy consumption for consumption during operation under energy-saving control if, theoretically, executed in response to a transient report. While this can often be obtained from, primarily, control providers, instead a calculating equation derived using a common multivariate analysis technique using the environmental conditions (outside temperature, number of occupants, room temperature setting value, etc.) as explanatory variables, using historical data for operations under the same control or similar control for the applicable building or other cases may be used, or cases of operation under similar conditions may be extracted from a database of operating history and the energy consumption corresponding to those extracted cases may be used. Here it is possible to use historical data for operations in the building in a case such as changing only a control parameter for the control that is currently in operation (such as, for example, changing a setting value). Moreover, the rate of reduction of the energy consumption if operating under the energy-saving control that, theoretically, can be used, relative to the energy consumption under the current control operations, is generally understood, then the energy consumption could be estimated using this and the wi.

For ease in explanation, it is assumed that the rate of reduction of the energy consumption has been established in the present example. In this case, an equation of ∫(1−P)×wi·dt (with the integration time being the operating time band for the energy-saving control that, theoretically, would be executed) is stored as the calculating equation for the theoretical energy consumption in the theoretical energy consumption calculating equation storing portion 7-11 (where, in the below, pw is defined as (1−P)×wi, so this calculating equation is written as ∫pw·dt). Here P represents the rate of reduction in the energy consumption at the time of the transient report-response energy-saving control operation, relative to operating under the current control, where, in the present example, P is set to 0.2 (20%).

Note that when deriving, through the common multivariate analysis technique, described above, a function F for calculating the theoretical energy consumption using, for example, the outside temperature tout, the temperature setting tsp, and the room temperature tpv, a calculating equation for the theoretical energy consumption such as=∫F(tout, tsp, tpv)·dt can be stored as the calculating equation. Because this is a function that is derived using the historical operating data, normally the input variables (in this case, the outside temperature, the temperature settings, and the room temperature) can be obtained as control information pertaining to the operation of the facility in the building, and the values thereof can be used to calculate the theoretical energy consumption easily.

### Calculating the Possible Energy Savings

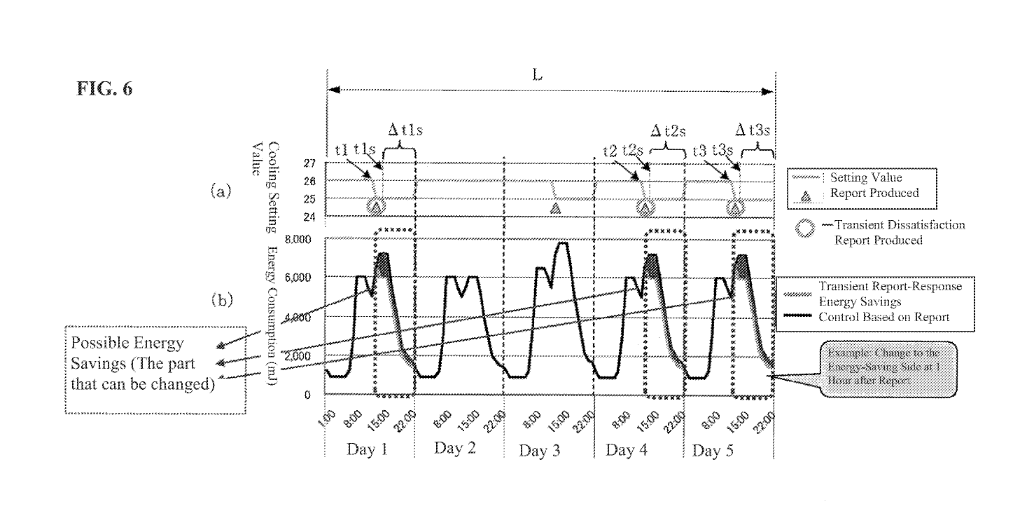

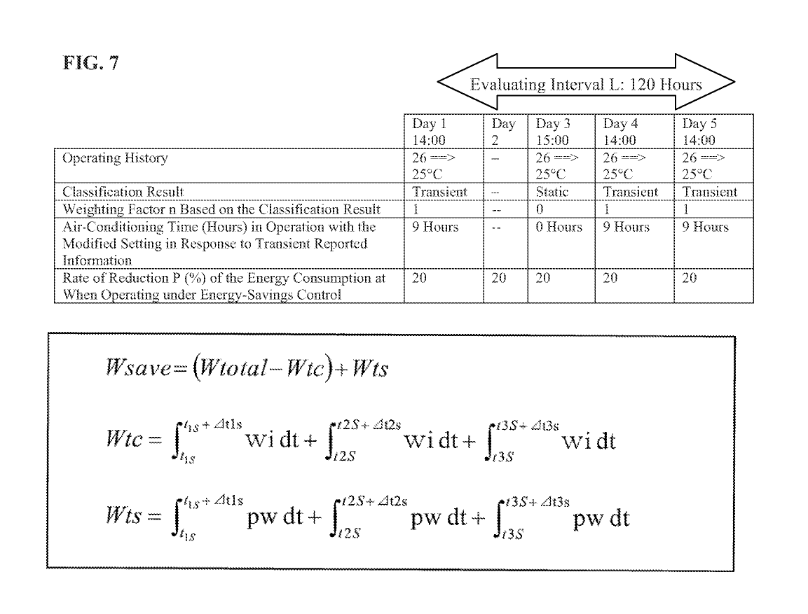

A specific example of the process for extracting the theoretical air-conditioning time bands for performing the transient report-response energy-saving control in the energy-saving control theoretical air-conditioning time band extracting portion 7-10, and the process for calculating the possible energy savings in the possible energy savings calculating portion 7-12 is explained in detail using FIG. 6 and FIG. 7.

Here FIG. 6(a) shows the changes in the cooling setting value tsp during the evaluating interval L, and FIG. 6(b) shows a time series of the actual values wi for the energy consumption during the evaluating interval L. FIG. 7 shows the operating history of the air-conditioning equipment, the classification results for the reported information, the weighting factors n depending on the classification results, the theoretical air-conditioning time for performing the transient report-response energy-saving control, and the reduction rate P of the energy consumption at the time of energy-saving control operations.

In this example, the evaluating interval L is 120 min. (five hours), where there was a transient report at 14:00 on Day 1, a static report at 15:00 on Day 3, and transient reports at 14:00 on Day 4 and 14:00 on Day 5. In order to respond to these, the cooling setting value was changed from 26° C. to 25° C. at 14:00 on Day 1, and returned to 26° C. at “0:00” that night. Moreover, the heating setting value was changed from 26° C. to 25° C. at 15:00 on Day 3, and returned to 26° C. at “0:00” that night. Similarly, the cooling setting value was changed from 26° C. to 25° C. at 14:00 on Day 4 and the heating setting value was changed from 26° C. to 25° C. at 14:00 on Day 5.

In this case, the classification executing portion 7-2 follows the classification procedure that has been set to classify the reports on Day 1, Day 4, and Day 5 as transient reports, and classify the report from Day 3 as a static report, and stores the classification results in the classification result storing portion 7-3. Moreover, the history of the air-conditioning operation during these five days is stored in the air-conditioning operation history storing portion 7-4.

The energy-saving control theoretical air-conditioning time band extracting portion 7-10 acquires the classification results for the reported information during the evaluating interval L which have been stored in the classification result storing portion 7-3, and defines the weighting factor n as “0” for the case of the classification result being a static report, and defines the weighting factor n as “1” for the case of a transient report. In this case, the weighting factors n are set to “0” for the reports on Day 1, Day 4, and Day 5, because they are transient reports, and the weighting factor n is set to “1” for the report on Day 3, because it is a static report.

Following this, the energy-saving control theoretical air-conditioning time band extracting portion 7-10 calculates the theoretical air-conditioning time bands over which the transient report-response energy-saving control can be performed, based on the air-conditioning operating history of the evaluating interval L that is stored in the air-conditioning operating history storing portion 7-4. In the present example, it is assumed that the transient report-response energy-saving control is performed by returning the temperature setting tsp to the building control setting tsp_{BIL} after one hour has elapsed after the transient report was produced, that is, the theoretical air-conditioning time band for performing the transient report-response energy-saving control assumes the performance of control that changes the setting value further to the energy-saving side than in the case of executing control in response to a static report.

In this example, for Day 1 the cooling setting value is changed from 26° C. to 25° C. at 14:00 and returned to 26° C. at 0:00, so because in this setting change operation the setting value is changed to the building-controlled temperature tsp_{BIL} at 15:00, which is one hour after the air-conditioning control starting time of the operation with the changed setting, and thus 15:00 through 0:00 on Day 1, which is the subsequent nine hours, is extracted. Similarly, for Day 3, 16:00 through 0:00 on Day 3, which is the eight hours after the setting value is changed, is extracted, and, for Day 4, 15:00 through 0:00 on Day 4, which is the nine hours after the setting value is changed, are extracted, and, for Day 5, 15:00 through 0:00 on Day 5, which is the nine hours after the setting value is changed, are extracted.

Given this, the theoretical air-conditioning time bands for executing the transient report-response energy-saving control are extracted depending on the weighting factors n for each report. In this example, the weighting factors n are “1” for Day 1, Day 4, and Day 5, and thus the theoretical air-conditioning time bands for performing the transient report-response energy-saving control will be 15:00 through 00:00 on Day 1, 15:00 through 0:00 on Day 4, and 15:00 through 0:00 on Day 5. For simplicity in the explanation below, the respective starting times are be defined as T1s, T2s, and T3s, and the time over which it continues is be defined as ΔT1s, ΔT2s, and ΔT3s, where the theoretical air-conditioning time bands are defined, respectively, as (T1s through ΔT1s+ΔT1s), (T2s through T2s+ΔT2s), and (T3s through T3s+ΔT3s). Here ΔT1s, ΔT2s, and ΔT3s correspond to “9 hours,” “9 hours,” and “9 hours.”

The possible energy savings calculating portion 7-12 calculates an estimated energy consumption Wsave, for the case wherein the transient report-response energy-saving control is performed, theoretically, when there is a transient report during the evaluating interval L, from the theoretical air-conditioning time band for performing the transient report-response energy-saving control, extracted by the energy-saving control theoretical air-conditioning time band extracting portion 7-10, the calculating equation (∫pw·dt) for the transient report-response energy-saving control equation that is stored in the theoretical energy consumption calculating equation storing portion 7-11, and the actual values wi for the energy consumption, stored in the energy consumption storing portion 7-6.

In this case, the energy consumption Wtc, which is the energy consumption for the actual consumption in the aforementioned theoretical air-conditioning time band (the theoretical air-conditioning time band T1s through T1s+ΔT1s for executing the transient report-response energy-saving control on Day 1, the theoretical air-conditioning time band T2s through T2s+ΔT2s for executing the transient report-response energy-saving control on Day 4, and the theoretical air-conditioning time band T3s through T3s+ΔT3s for executing the transient report-response energy-saving control on Day 5) is calculated through Equation (2-1), below, and the theoretical energy consumption Wts for the case wherein, theoretically, the transient report-response energy-saving control could have been performed during these theoretical air-conditioning time bands can be calculated through Equation (2-2), below, based on the calculating equation stored in the theoretical energy consumption calculating equation storing portion 7-11. Moreover, the estimated energy consumption Wsave for the case of executing, theoretically, the transient report-response energy-saving control for the transient reports during the evaluating interval L can be calculated through Equation (3), below, using the energy consumption for the actual consumption in other than the theoretical air-conditioning time band (Wtotal−Wtc) (where Wtotal here is the energy consumption for the actual consumption during the evaluating interval L) and the theoretical energy consumption Wts,

[Equation 2]

Wtc=∫ [symbol] [symbol] widt+∫ [symbol] [symbol] widt+∫ [symbol] [symbol] widt (2-1)

Wts=∫ [symbol] [symbol] pwdt+∫ [symbol] [symbol] pwdt+∫ [symbol] [symbol] pwdt (2-2)

Wsave=(Wtotal−Wtc)+Wts 3)

Given this, the possible energy savings calculating portion 7-12 calculates, as the possible energy savings during the evaluating interval L, a comparison value, indicated through a difference, a ratio, or the like, between the energy consumption Wtotal for the actual consumption during the evaluating interval L and the estimated energy consumption Wsave for the case wherein, theoretically, the transient report-response energy-saving control would have been performed in response to transient reports during the evaluating interval L. These calculated possible energy savings are displayed on the displaying portion 7-9.

The estimated energy consumption Wsave, shown in the present example, or an index, such as the possible energy savings, or the like, obtained using the Wsave, corresponds to the evaluation index for the operating status of the facility in the present invention. The use of the estimated energy consumption Wsave is calculated based on the classification result (i.e., transient vs. static) for the reported information makes it possible to exclude, at the time of the energy evaluation, the effects of reports of transient desires, which cannot be considered to be caused by the performance or operation of the facility, thus enabling a substantial improvement in the validity of the evaluation index, and enabling more correct evaluations of the operating status of the air-conditioning equipment within a building.

Note that while in this example the theoretical energy consumption for the transient report-response energy-saving control was calculated by assuming consumption of energy in the energy-saving control that, theoretically, can be executed to be a P% decrease in the energy consumption for the consumption under the control that was actually executed, instead the theoretical energy consumption for the consumption if the energy-saving control were, theoretically, applied may be calculated through various types of energy calculations based on the properties of the building.

Moreover, while in this example it was assumed that control was performed wherein the temperature setting tsp would be returned to the building-controlled temperature tsp_{BIL} after one hour elapsed after the transient report, as the transient report-response energy-saving control, instead this may be designed as appropriate such as shortening the time that must elapse before returning the temperature setting, gradually returning the temperature setting tsp, setting the temperature setting tsp, which is changed in response to the transient report, to a value that is further changed to the energy savings side than in the case of responding to a static report, or the like.

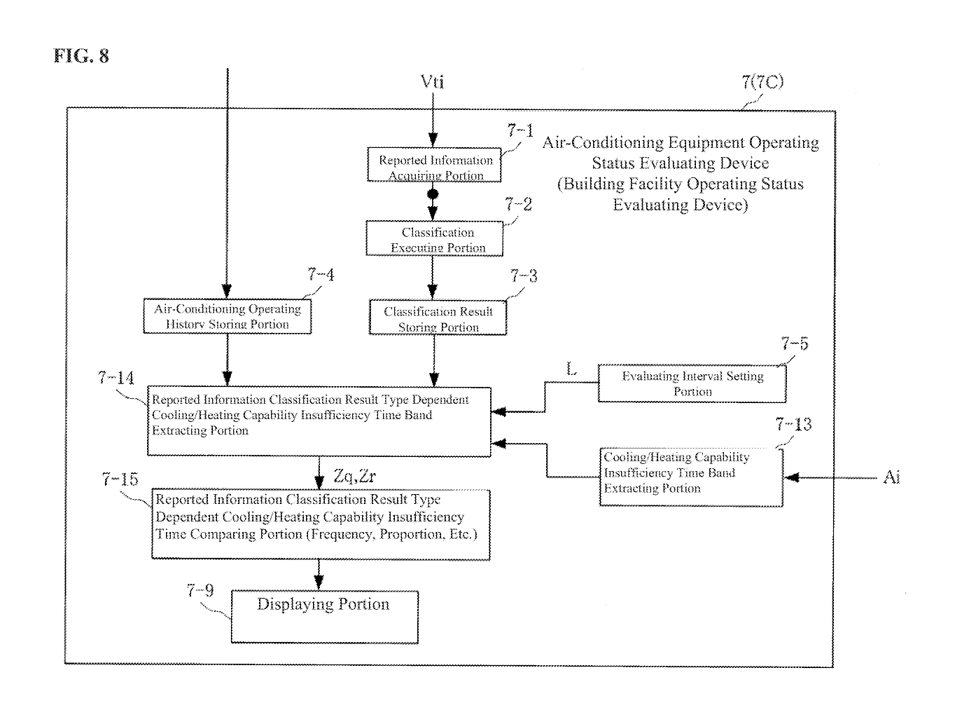

FIG. 8 is illustrates a function block of an air conditioning equipment operating status evaluating device in the case of deriving an evaluation index from the perspective of the environment (comfort) as another example of an air conditioning equipment operating status evaluating device 7 illustrated in FIG. 1.

In this air-conditioning equipment operating status evaluating device 7 (7C), the “function block for reported information classification” is identical to that of the air-conditioning equipment operating status evaluating device 7A in the above examples, so the explanation thereof is omitted.

Function Block for the Evaluation index Calculation

This air-conditioning equipment operating status evaluating device 7C is provided with: an evaluating interval setting portion 7-5 for setting an evaluating interval; a cooling/heating capability insufficiency time band extracting portion 7-13 for extracting a cooling/heating capability insufficiency time band from surplus/deficiency information Ai for the heating/cooling capability, inputted periodically; a reported information classification result type-dependent cooling/heating capability insufficiency time band extracting portion 7-14 for calculating a cooling/heating capability insufficiency time for each type of reported information classification result during an evaluating interval L; a reported information classification result type-dependent cooling/heating capability insufficiency time comparing portion 7-15 for comparing the cooling/heating capability insufficiency times for each type of reported information classification result in the evaluating interval L; and a displaying portion 7-9.

Note that in this example, the surplus/deficiency information Ai for the cooling/heating capability is provided as, for example, information on the degree of opening of a chilled water valve 3 (in FIG. 1), where if the degree of opening of the chilled water valve 3 100%, then it can be concluded that the cooling/heating capability is insufficient.

Moreover, although not illustrated in FIG. 1, if a variable air flow adjusting device (VAV) for adjusting the rate of air supply from an air conditioner 2 into a living space 1 is provided, then one may consider the air flow rate information of the VAV to be cooling/heating capability surplus/deficiency information Ai. In this case, if the VAV air flow rate is at a maximum, it can be determined that the cooling/heating capability is insufficient.

Additionally, the time that has elapsed since arriving at a specific condition, such as the aforementioned valve opening information or VAV air flow rate information being 100% or a maximum air flow rate, or the like, may be the surplus/insufficiency information, where if a specific amount of time has elapsed it can be determined that the cooling/heating capability is insufficient. The conditions for evaluating the cooling/heating capability insufficiency that are used commonly in air-conditioning of buildings should be established as appropriate, where the information required for the evaluation would be the surplus/deficiency information Ai for the cooling/heating capability.

When the cooling/heating capability is insufficient, there will often be a loss of comfort in the living space 1, with the room temperature tpv not tracking the setting temperature tsp. As can be understood from this, the surplus/insufficiency information Ai for the cooling/heating capability is environmental information pertaining to the comfort within the living space 1, where this cooling/heating capability surplus/insufficiency information Ai corresponds to typical control information regarding the operation of the facility in the building in the present example.

### Calculating the Cooling/Heating Capability Insufficiency Time for Each Type of Reported Information Classification Result

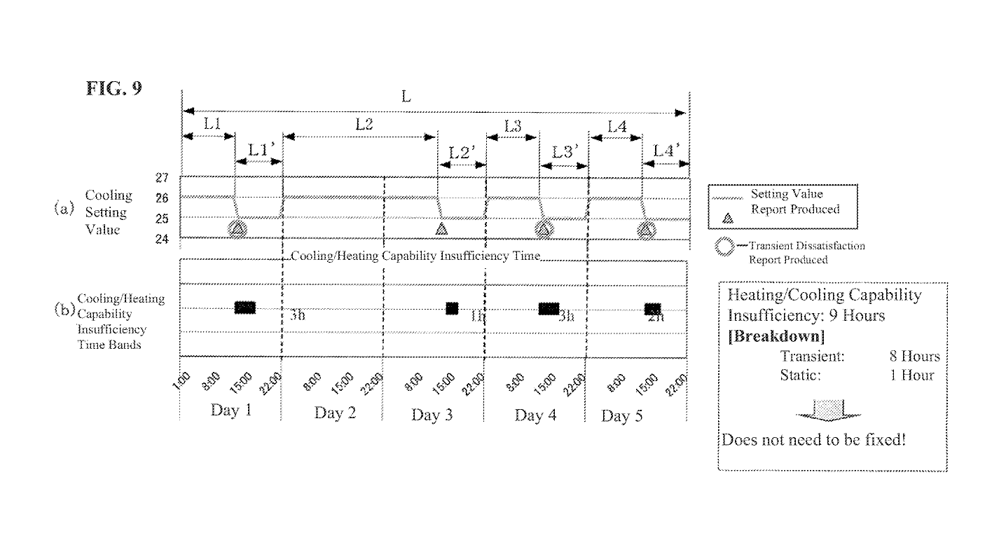

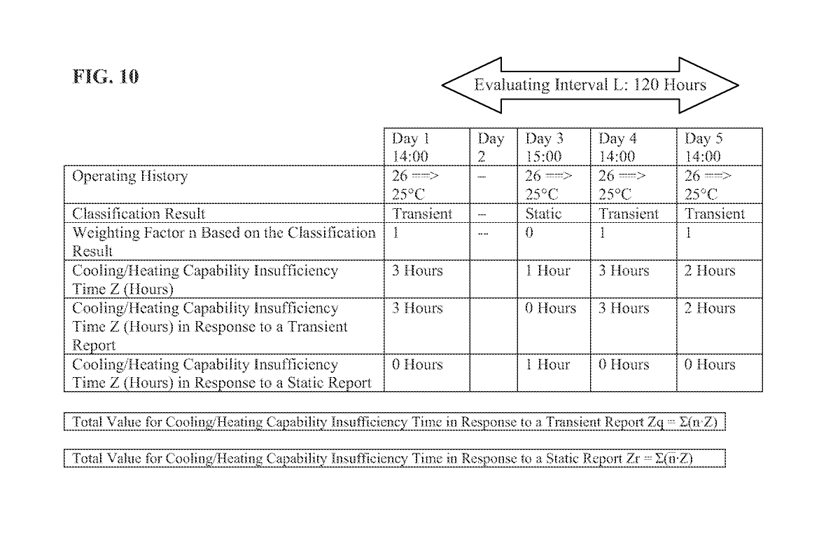

A specific example of the process for calculating the cooling/heating capability insufficiency time for each type of reported information classification result, by the reported information classification result type-dependent cooling/heating capability insufficiency time calculating portion 7-14, will be explained using FIG. 9 and FIG. 10.

Here FIG. 9(a) shows the changes in the cooling setting value tsp during the evaluating interval L, and FIG. 9(b) shows the time bands wherein the cooling/heating capability is insufficient during the evaluating interval L. FIG. 10 shows the operating history of the air-conditioning equipment, the classification results for the reported information, the weighting factors n depending on the classification results, the cooling/heating capability insufficiency time Z, the transient report-response heating/cooling capability insufficiency time Zq, and the static report-response cooling/heating capability insufficiency time Zr.

In this example, the evaluating interval L is 120 min. (five hours), where there was a transient report at 14:00 on Day 1, a static report at 15:00 on Day 3, and transient reports at 14:00 on Day 4 and 14:00 on Day 5. Given this, the heating setting value was changed from 26° C. to 25° C. at 02:00:00 PM on Day 1, and returned to 26° C. at “0:00” that night. Moreover, the heating setting value was changed from 26° C. to 25° C. at 15:00 on Day 3, and returned to 26° C. at “0:00” that night. Similarly, the cooling setting value was changed from 26° C. to 25° C. at 14:00 on Day 4 and the heating setting value was changed from 26° C. to 25° C. at 14:00 on Day 5.

In this case, the classification executing portion 7-2 follows the classification procedure that has been set to classify the reports on Day 1, Day 4, and Day 5 as transient reports, and classify the report from Day 3 as a static report, and stores the classification results in the classification result storing portion 7-3. Moreover, the history of the air-conditioning operation during these five days is stored in the air-conditioning operation history storing portion 7-4.

The reported information classification result type-dependent cooling/heating capability insufficiency time band extracting portion 7-14 acquires the classification results for the reported information during the evaluating interval L which have been stored in the classification result storing portion 7-3, and defines the weighting factor n as “0” for the case of the classification result being a static report, and defines the weighting factor n as “1” for the case of a transient report. In this case, the weighting factors n are set to “0” for the reports on Day 1, Day 4, and Day 5, because they are transient reports, and the weighting factor n is set to “1” for the report on Day 3, because it is a static report.

Given this, the reported information classification result type-dependent cooling/heating capability insufficiency time band extracting portion 7-14 calculates the cooling/heating capability insufficiency time Z for the air-conditioning time bands when operating with changed settings corresponding to each reported information. In this case, the cooling/heating capability insufficiency time Z is calculated as three hours for Day 1, one hour for Day 3, three hours for Day 4, and two hours for Day 5.

Moreover, the reported information classification result type-dependent cooling/heating capability insufficiency time band extracting portion 7-14 multiplies the cooling/heating capability insufficiency time Z in the operation with the changed settings in response to the reported information by the weighting factor n corresponding to the type of report, to calculate the cooling/heating capability insufficiency time corresponding to the transient reports. In this example, the weighting factor n for Day 1, Day 4, and Day 5 is “1”, so the cooling/heating capability insufficiency time is calculated as three hours, three hours, and two hours, but for Day 3, the weighting factor n is “0”, so the cooling/heating capability insufficiency time corresponding to the transient report is 0 hours.

Given this, the cooling/heating capability insufficiency times corresponding to the transient reports are summed to calculate the total value Zq for the cooling/heating capability insufficiency times corresponding to the transient reports in the evaluating interval L. In this case, the total value Zq for the cooling/heating capability insufficiency times corresponding to the transient reports during the evaluating interval L is calculated as Zq=8.

Moreover, the total value Zr for the cooling/heating capability insufficiency times corresponding to the static reports (that is, those that are not transient reports) during the evaluating interval L is calculated. Because Zr is the total value of the cooling/heating capability insufficiency time Ztotal=ΣZ during the evaluating interval L less the total value Zq for the heating/cooling capability insufficiency time corresponding to transient reports during the evaluating interval L, this may be calculated by inverting the weighting factors or calculating the total value Z corresponding to “1” (FIG. 10), and then calculating the value as Zr=(Ztotal−Zq). In any event, in this case the total value Zr for the cooling/heating capability insufficiency time corresponding to the static reports during the evaluating interval L is calculated as Zr=1 hour.

### Comparing the Cooling/Heating Capability Insufficiency Time for Each Type of Reported Information Classification Result

The reported information classification result type-dependent cooling/heating capability insufficiency time comparing portion 7-15 inputs the total value Zq for the cooling/heating capability insufficiency time corresponding to the transient reports during the evaluating interval L, calculated by the reported information classification result type-dependent cooling/heating capability insufficiency time band extracting portion 7-14, and the total value Zr (=Ztotal−Zq) of the cooling/heating capability insufficiency time corresponding to the static reports (those that are not transient), to calculate a comparison result for the cooling/heating capability insufficiency time for each type of reported information classification result.

For example, as the comparison result, a ratio (Zq/Zr)=Zq/(Ztotal−Zq) of the total time Zq of the cooling/heating capability insufficiency time corresponding to the transient reports relative to the total value Zr(=Ztotal−Zq) of the cooling/heating capability insufficiency time corresponding to the static reports (those that are not transient) is calculated. In this case, if the proportion is high, then the cooling/heating capability insufficiency time corresponding to the transient reports is large, implying that there are many cases wherein the cooling/heating capability insufficiency occurs in response to reports of transient desires, which cannot be considered to be caused by the performance or operation of the equipment, and thus it is possible to determine that countermeasures thereto are not particularly urgent. These comparison results that have been calculated are displayed on the displaying portion 7-9.

Note that while in this example the proportion of the total value Zq of the cooling/heating capability insufficiency time corresponding to the transient reports, relative to the total value Zr (=Ztotal−Zq) of the cooling/heating capability insufficiency time corresponding to static reports (those that are not transient) during the evaluating interval L was calculated as the evaluation index, instead the occurrence frequency of a cooling/heating capability insufficiency time band corresponding to transient reports and the Occurrence frequency of cooling/heating capability insufficiency time bands corresponding to static reports (those that are not transient) may be compared and the comparison results may be displayed as the evaluation results.

Additionally, Zr/Zq (=(Ztotal−Zq)/Zq, with Zq as the basis for the comparison, may be calculated as the evaluation index, or Zq/Ztotal, or Zr/Ztotal (=Ztotal−Zq)/Ztotal, with Ztotal as the basis, may be calculated as the evaluation index. All of these cases, that is, Zq/(Ztotal−Zq), (Ztotal−Zq)/Zq, Zq/Ztotal, or (Ztotal−Zq)/Ztotal, are forms of an evaluation index that is calculated from the total time Ztotal for the cooling/heating capability insufficiency time bands during the evaluating interval L and the total value Zq for the cooling/heating capability insufficiency time corresponding to the transient reports during the evaluating interval L.

The total value Zr of the cooling/heating capability insufficiency time corresponding to the static reports in the present example, or the indices such as Zq/Zr, Zr/Zq, Zq/(Zq+Zr), and Zr/(Zq+Zr), and the like, obtained using this Zr, correspond to the evaluation index for the operating status of the equipment in the present examples. The use of the total value Zr of the cooling/heating capability insufficiency time corresponding to the static reports, calculated based on the classification result (i.e., transient vs. static) for the reported information makes it possible to exclude, at the time of the environment evaluation corresponding to reports of transient desires, which cannot be considered to be caused by the performance or operation of the facility, thus enabling a substantial improvement in the validity of the evaluation index, and enabling more correct evaluations of the operating status of the air-conditioning equipment within a building.

Moreover, those time bands in the evaluating interval L that are other than the time bands wherein air conditioning control is performed using reported information that is classified as transient reports as evaluation-applicable time bands, and the evaluation index may be calculated from the total time of these evaluation-applicable time bands and the total time of the cooling/heating capability insufficiency time bands within these evaluation-applicable time bands.

Explaining in reference to FIG. 9, for example, in this case, during the evaluating interval L, time bands L1, L2, L2′, L3, and L4, which are other than the time bands L1′, L3′, and L4′, wherein air conditioning control was performed in response to transient reports, are defined as the evaluation-applicable time bands. Given this, the times of these evaluation-applicable time bands L1, L2, L2′, L3, and L4 are totaled, and the evaluation index is calculated from the total time of the coating/heating capability insufficiency time bands within the totaled evaluation-applicable time bands (which, in this case, are L2′, which is one hour on Day 3), For example, the proportion of the total time L2′ (one hour) of the cooling/heating capability insufficiency time bands in the evaluation-applicable time bands, relative to the total time of the evaluation-applicable time bands L1, L2, L2′, L3, and L4 is used as the evaluation index.

Moreover, because the calculated evaluation index is displayed on the displaying portion 7-9 in the examples set forth above, an individual viewing the evaluation index may determine whether or not it is necessary to adjust air conditioning controlling parameters or whether or not it is necessary to modify the air-conditioning equipment, in this case, a threshold value may be displayed as a decision criterion to enable a decision as to whether or not modifications to the air conditioning controlling parameters or modifications to the air-conditioning equipment are necessary through a comparison with the threshold value. Moreover, comparisons of the evaluation index with threshold values may be performed in the possible energy savings calculating portions 7-8 or 7-12 and in the reported information classification result type-dependent cooling/heating capability insufficiency time comparing portion 7-15, and the comparison result maybe displayed on the displaying portion 7-9.

Moreover, the evaluation index calculated in the possible energy savings calculating portion 7-8 or 7-12, or in the reported information classification result type-dependent cooling/heating capability insufficiency time comparing portion 7-15 may be sent to a center through a communication network for a decision regarding the evaluation index to be made on a screen in the center, or it may be printed out as an operating report.

Moreover, while the explanation in the examples set forth above were for air conditioning equipment as the facilities operated using the reported information, there is similar applicability also to other types of facilities, such as lighting equipment. In the case of lighting equipment, the reported information would indicate desires, such as dissatisfaction, regarding the brightness, and the like.

The building facility operating status evaluating method and device according to the examples of the present invention, as a method and device for classifying whether or not reported information from a user of a building is due to a transient factor, to calculate an evaluation index that can evaluate more property the operating status of the facility within the building through the use of the reported information classification result, can be used in modifying facilities, such as air-conditioning equipment and lighting equipment, modifying control parameters such as air conditioning control parameters and lighting control parameters, and so forth.

1. A building facility operating status evaluating method for a facility that is operated using reported information from a user of a building, comprising:
a reported information acquiring step acquiring reported information from the user;
a reported information classifying step classifying whether or not the acquired reported information is transient reported information due to a transient factor; and
an evaluation index calculating step calculating an evaluation index evaluating an operating status of a facility in the building based on a classification result of reported information and on the control information regarding the operation of the facility in the building.

2. The building facility operating status evaluating method as set forth in claim 1, wherein:
the evaluation index is an evaluation index indicating the operating status in relation to energy.

3. The building facility operating status evaluating method as set forth in claim 1, wherein:
the evaluation index is an evaluation index indicating the operating status in relation to the environment.

4. The building facility operating status evaluating method as set forth in claim 2, wherein:
the evaluation index calculating step defines, as an evaluation-applicable time band, a time band within a specific evaluating interval other than a time band wherein operation of the facility is performed using reported information classified as transient reported information, and calculates the evaluation index from a total time for the evaluation-applicable time bands and an actual value for energy consumed in the operation of the facility in the evaluation-applicable time bands.

5. The building facility operating status evaluating method as set forth in claim 2, wherein:
the evaluation index calculating step defines a specific evaluating interval as an evaluation-applicable time band, and calculates the evaluation index from a theoretical value for the energy that would he consumed in a theoretical application of an operation of the facility wherein a condition has been relaxed to the side wherein energy savings are achieved in a time band wherein the facility is operated using reported information classified as transient reported information, and an actual value for energy consumed in operating the facility in a time band other than a time band wherein the operation of the facility was performed using reported information classified as transient reported information.

6. The building facility operating status evaluating method as set forth in claim 3, wherein:
the evaluation index calculating step defines, as an evaluation-applicable time band, a time band in a specific evaluating interval wherein an operating capability of the facility has fallen into an insufficient state, and calculating the evaluation index from a total time for the evaluation-applicable time bands and a total time for a time band wherein the facility is operated using reported information classified as transient reported information.

7. The building facility operating status evaluating method as set forth in claim 3, wherein:
the evaluation index calculating step calculates a time band outside of a time band wherein the operation of the facility uses reported information classified as transient information, within the specific evaluating interval, to define a evaluation-applicable time band, and derives an evaluation index from the total time of the evaluation-applicable time bands and the total time of the time bands wherein, during the evaluation-applicable time bands, the operating capability of the facility has fallen into an insufficient state.

8. The building facility operating status evaluating method as set forth in claim 1, wherein:
the reported information classifying step classifies whether or not the acquired reported information is transient reported information using room occupancy time information regarding the user, reported information from after an arbitrary time interval has elapsed, reporting reason information, reporting history, and/or reporting patterns amongst the users as a whole.

9. A building facility operating status evaluating device for a facility that is operated using reported information from a user of a building, comprising:
a reported information acquiring device acquiring reported information from the user;
a reported information classifying device classifying whether or not the acquired reported information is transient reported information due to a transient factor; and
an evaluation index calculating device calculating an evaluation index for evaluating an operating status of a facility in the building based on a classification result of reported information and on the control information regarding the operation of the facility in the building.

10. The building facility operating status evaluating device as set forth in claim 9, wherein:
the evaluation index is an evaluation index indicating the operating status in relation to energy.

11. The building facility operating status evaluating device as set forth in claim 9, wherein:
the evaluation index is an evaluation index indicating the operating status in relation to the environment.

12. The building facility operating status evaluating device as set forth in claim 10, wherein:
the evaluation index calculating device defines, as an evaluation-applicable time band, a time band within a specific evaluating interval other than a time band wherein operation of the facility is performed using reported information classified as transient reported information, and calculates the evaluation index from a total time for the evaluation-applicable time bands and an actual value for energy consumed in the operation of the facility in the evaluation-applicable time bands.

13. The building facility operating status evaluating device as set forth in claim 10, wherein:
the evaluation index calculating device defines a specific evaluating interval as an evaluation-applicable time band, and calculates the evaluation index from a theoretical value for the energy that would be consumed in a theoretical application of an operation of the facility wherein a condition has been relaxed to the side wherein energy savings are achieved in a time band wherein the facility is operated using reported information classified as transient reported information, and an actual value for energy consumed in operating the facility in a time band other than a time band wherein the operation of the facility was performed using reported information classified as transient reported information.

14. The building facility operating status evaluating device as set forth in claim 11, wherein:
the evaluation index calculating device defines, as an evaluation-applicable time band, a time band in a specific evaluating interval wherein an operating capability of the facility has fallen into an insufficient state, and calculating the evaluation index from a total time for the evaluation-applicable time bands and a total time for a dine band wherein the facility is operated using reported information classified as transient reported information.

15. The building facility operating status evaluating device as set forth in claim 11, wherein:
the evaluation index calculating device
calculates a time band outside of a time band wherein the operation of the facility uses reported information classified as transient information, within the specific evaluating interval, to define a evaluation-applicable time band, and derives an evaluation index from the total time of the evaluation-applicable time bands and the total time of the time bands wherein, during the evaluation-applicable time bands, the operating capability of the facility has fallen into an insufficient state.

16. The building facility operating status evaluating device as set forth in claim 9, wherein:
the reported information classifying device
classifies whether or not the acquired reported information is transient reported information using room occupancy time information regarding the user, reported information from after an arbitrary time interval has elapsed, reporting reason information, reporting history, and/or reporting patterns amongst the users as a whole.
